(19) United States
(12) Patent Application Publication
(10) Pub. No.: US 2021/0343837 A1
(43) Pub. Date: Nov. 4, 2021

(54) SEMICONDUCTOR STRUCTURES

(71) Applicant: Vanguard International Semiconductor Corporation, Hsinchu (TW)

(72) Inventors: Shih-Chieh CHIEN, Nantou City (TW); Chia-Hao LEE, New Taipei City (TW); Din-Ru YANG, Hsinchu City (TW); Chia-Shen LIU, Hsinchu City (TW)

(73) Assignee: Vanguard International Semiconductor Corporation, Hsinchu (TW)

(21) Appl. No.: 16/864,498

(22) Filed: May 1, 2020

(51) Int. Cl. H01L 29/06

(52) U.S. Cl. CPC H01L 29/0623

(57) ABSTRACT

A semiconductor structure is provided. The semiconductor structure includes a substrate, a plurality of strip first doped regions formed in the substrate, a plurality of strip second doped regions formed in the substrate and respectively located between the strip first doped regions, a third doped region formed in the substrate and surrounding the strip first doped regions and the strip second doped regions, and a fourth doped region formed in the substrate and located underneath the strip first doped regions, the strip second doped regions and the third doped region. The doping type of the strip first doped region is the opposite of that of the strip second doped region. The doping type of the third doped region is the same as that of the strip second doped region. The doping type of the fourth doped region is the same as that of the strip second doped region.

### BACKGROUND OF THE INVENTION

### Field of the Invention

The present invention relates to a semiconductor structure, and, in particular, to a semiconductor structure with strip doped regions.

### Description of the Related Art

Due to functional considerations, if an additional high-voltage diode component is introduced into a general circuit system with high-voltage components, an N-well region must be disposed underneath the high-voltage diode component to form an isolation structure between the high-voltage diode component and the substrate. However, the arrangement of the N-well region may lower the junction breakdown voltage of the high-voltage diode component. As a result, the high-voltage diode component cannot meet operational requirements.

At present, reducing the concentration of the N-well region is one way to improve junction breakdown voltage. Although this method can moderately increase the junction breakdown voltage of the high-voltage diode components, however, it may also reduce the breakdown voltage of other high-voltage components in the same circuit system, affecting the electrical stability of such components.

Therefore, how to development of a semiconductor structure capable of improving junction breakdown voltage (BV) of high-voltage diode components and maintaining electrical stability of other high-voltage components in the same circuit system is desirable.

### BRIEF SUMMARY OF THE INVENTION

In accordance with an embodiment of the present invention, a semiconductor structure is provided. The semiconductor structure includes a substrate, a plurality of strip first doped regions, a plurality of strip second doped regions, a third doped region, and a fourth doped region. The strip first doped regions are formed in the substrate. The strip second doped regions are formed in the substrate and located between respective strip first doped regions. The third doped region is formed in the substrate and surrounds the strip first doped regions and the strip second doped regions. The fourth doped region is formed in the substrate and is located underneath the strip first doped regions, the strip second doped regions, and the third doped region. In addition, the doping type of the strip first doped region is the opposite of that of the strip second doped region. The doping type of the third doped region is the same as that of the strip second doped region. The doping type of the fourth doped region is the same as that of the strip second doped region.

In accordance with some embodiments, the substrate is a P-type substrate or an N-type substrate. In accordance with some embodiments, when the substrate is a P-type substrate, the doping type of the strip first doped region is P type, the doping type of the strip second doped region is N type, the doping type of the third doped region is N type, and the doping type of the fourth doped region is N type. In accordance with some embodiments, when the substrate is an N-type substrate, the doping type of the strip first doped region is N type, the doping type of the strip second doped region is P type, the doping type of the third doped region is P type, and the doping type of the fourth doped region is P type.

In accordance with some embodiments, the strip first doped region has a width which is the same as that of the strip second doped region. In accordance with some embodiments, the strip first doped region has a depth in the substrate which is the same as that of the strip second doped region. In accordance with some embodiments, the third doped region has a depth in the substrate which is greater than that of the strip first doped region and the strip second doped region. In accordance with some embodiments, the strip first doped region, the strip second doped region and the third doped region have the same doping concentration. In accordance with some embodiments, the fourth doped region has a doping concentration which is lower than that of the strip first doped region, the strip second doped region and the third doped region.

In accordance with some embodiments, the fourth doped region is a continuous doped region. In accordance with some embodiments, the strip first doped region is a high-voltage P-well (HVPW) region, and the strip second doped region and the third doped region are high-voltage N-well (HVNW) regions. In accordance with some embodiments, the strip first doped regions, the strip second doped regions and the third doped region constitute a plurality of high-voltage diodes.

In accordance with an embodiment of the present invention, a semiconductor structure is provided. The semiconductor structure includes a substrate, a first doped region formed in the substrate, a second doped region formed in the substrate and surrounding the first doped region, and a plurality of strip third doped regions formed in the substrate and located underneath the first doped region and the second doped region. In addition, the first doped region has a doping type which is the opposite of that of the second doped region. The strip third doped region has a doping type which is the same as that of the second doped region.

In accordance with some embodiments, the substrate is a P-type substrate or an N-type substrate. In accordance with some embodiments, when the substrate is a P-type substrate, the doping type of the first doped region is P type, the doping type of the second doped region is N type, and the doping type of the strip third doped region is N type. In accordance with some embodiments, when the substrate is an N-type substrate, the doping type of the first doped region is N type, the doping type of the second doped region is P type, and the doping type of the strip third doped region is P type.

In accordance with some embodiments, the first doped region has a depth in the substrate which is the same as that of the second doped region. In accordance with some embodiments, the first doped region has a doping concentration which is the same as that of the second doped region. In accordance with some embodiments, the strip third doped region has a doping concentration which is lower than that of the first doped region and the second doped region. In accordance with some embodiments, the strip third doped regions have the same width.

In accordance with some embodiments, the strip third doped regions are separated from each other. In accordance with some embodiments, the first doped region is a high-voltage P-well (HVPW) region, and the second doped region is a high-voltage N-well (HVNW) region. In accordance with some embodiments, the first doped region and the second doped region constitute a plurality of high-voltage diodes.

By adjusting the doping profile, the present invention replaces the conventional high-voltage P-well (HVPW) region extending over the entire substrate surface to form a plurality of doped regions in the form of strips. The strip high-voltage P-well (HVPW) regions are combined with a plurality of high-voltage N-well (HVNW) regions and arranged in such a way that they alternate with each other to form the specific high-voltage diode structure. Due to the arrangement of the plurality of strip doped regions of the present invention, the junction area of the P-N is greatly increased, so that the high-voltage diode can effectively disperse the generated electric field during operation, even in the presence of the deep N-well (DNW) region, the breakdown voltage (BV) of the high-voltage diode can still greatly increased by more than 80%. In addition, the present invention can directly introduce the above-mentioned high-voltage diode structure without changing the MOS processes, the implanting conditions, and the photomask combination. The present invention does not affect the breakdown voltage (BV) of other high-voltage components provided in the same circuit system as the above-mentioned high-voltage diode structure, ensuring the electrical stability of such high-voltage components, thereby maintaining the stability and performance of the overall circuit.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 shows a top view of a semiconductor structure in accordance with an embodiment of the invention;

FIG. 2 shows a cross-sectional view of the semiconductor structure shown in FIG. 1 taken along the A-A′ cross-sectional line;

FIG. 3 shows a top view of a semiconductor structure in accordance with an embodiment of the invention;

FIG. 4 shows a cross-sectional view of the semiconductor structure shown in FIG. 3 taken along the B-B′ cross-sectional line; and

FIG. 5 shows a breakdown voltage (BV) value of a semiconductor structure in accordance with an embodiment of the invention.

### DETAILED DESCRIPTION OF THE INVENTION

The following description is made for the purpose of illustrating the general principles of the invention and should not be taken in a limiting sense. The scope of the invention is best determined by reference to the appended claims.

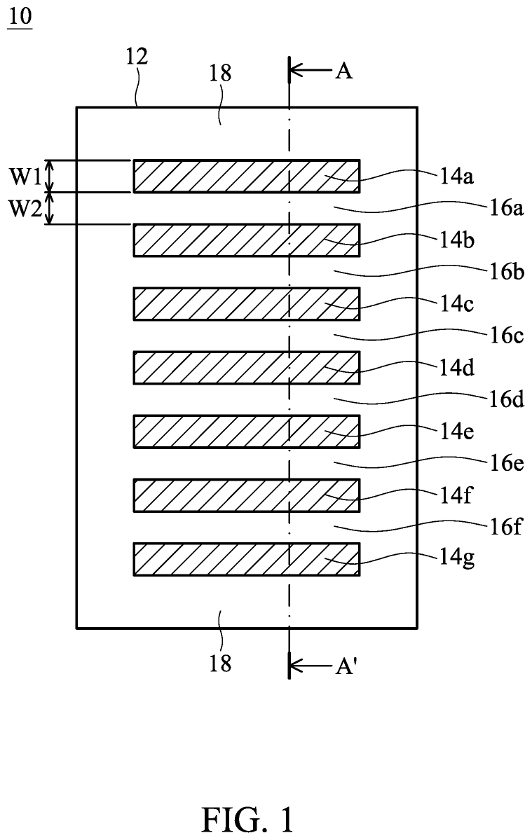

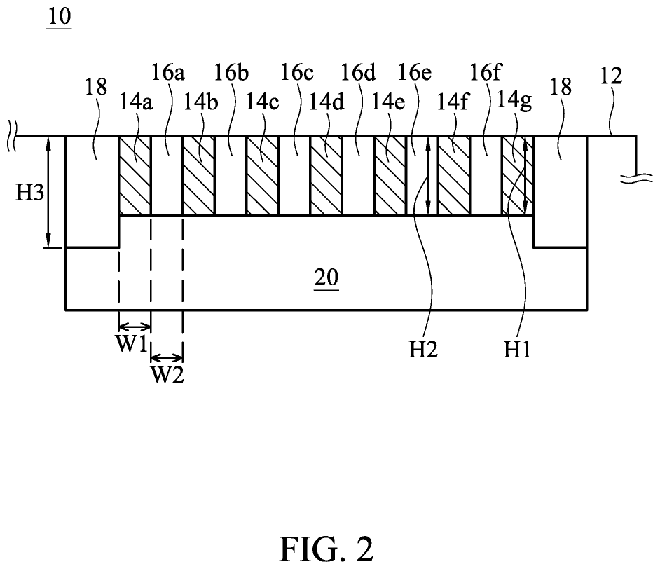

Referring to FIGS. 1 and 2, in accordance with an embodiment of the invention, a semiconductor structure 10 is provided. FIG. 1 is a top view of the semiconductor structure 10. FIG. 2 shows a cross-sectional view of the semiconductor structure 10 shown in FIG. 1 taken along the A-A′ cross-sectional line.

As shown in FIGS. 1 and 2, the semiconductor structure 10 includes a substrate 12, a plurality of strip first doped regions (14a, 14b, 14c, 14d, 14e, 14f and 14g), a plurality of strip second doped regions (16a, 16b, 16c, 16d, 16e and 16f), a third doped region 18 and a fourth doped region 20. The strip first doped regions (14a, 14b, 14c, 14d, 14e, 14f and 14g) are formed in the substrate 12. The strip second doped regions (16a, 16b, 16c, 16d, 16e and 16f) are formed in the substrate 12 and respectively located between the strip first doped regions (14a, 14b, 14c, 14d, 14e, 14f and 14g). For example, the strip first doped regions (14a, 14b, 14c, 14d, 14e, 14f and 14g) and the strip second doped regions (16a, 16b, 16c, 16d, 16e and 16f) are arranged in such a way that they alternate with each other. In FIGS. 1 and 2, the starting point and the ending point of the arrangement of the strip first doped regions (14a, 14b, 14c, 14d, 14e, 14f and 14g) and the strip second doped regions (16a, 16b, 16c, 16d, 16e and 16f) are both the strip first doped regions (for example, 14a and 14g). The third doped region 18 is formed in the substrate 12 and surrounds the strip first doped regions (14a, 14b, 14c, 14d, 14e, 14f and 14g) and the strip second doped regions (16a, 16b, 16c, 16d, 16e and 16f). The third doped region 18 is substantially in contact with the strip first doped regions (14a, 14b, 14c, 14d, 14e, 14f and 14g) and the strip second doped regions (16a, 16b, 16c, 16d, 16e and 16f). The fourth doped region 20 is formed in the substrate 12 and located underneath the strip first doped regions (14a, 14b, 14c, 14d, 14e, 14f and 14g), the strip second doped regions (16a, 16b, 16c, 16d, 16e and 16f) and the third doped region 18. The fourth doped region 20 is substantially in contact with the strip first doped regions (14a, 14b, 14c, 14d, 14e, 14f and 14g), the strip second doped regions (16a, 16b, 16c, 16d, 16e and 16f) and the third doped region 18. In some embodiments, the doping type of the strip first doped regions (14a, 14b, 14c, 14d, 14e, 14f and 14g) is the opposite of that of the strip second doped regions (16a, 16b, 16c, 16d, 16e and 16f). The doping type of the third doped region 18 is the same as that of the strip second doped regions (16a, 16b, 16c, 16d, 16e and 16f). The doping type of the fourth doped region 20 is the same as that of the strip second doped regions (16a, 16b, 16c, 16d, 16e and 16f).

In FIGS. 1 and 2, the doping types of the substrate 12, the strip first doped regions (14a, 14b, 14c, 14d, 14e, 14f and 14g), the strip second doped regions (16a, 16b, 16c, 16d, 16e and 16f), the third doped region 18 and the fourth doped region 20 are as follows. The substrate 12 is a P-type semiconductor substrate. The doping type of the strip first doped regions (14a, 14b, 14c, 14d, 14e, 14f and 14g) is P type. The doping type of the strip second doped regions (16a, 16b, 16c, 16d, 16e and 16f) is N type. The doping type of the third doped region 18 is N type. The doping type of the fourth doped region 20 is N type. In some embodiments, the substrate 12, the strip first doped regions (14a, 14b, 14c, 14d, 14e, 14f and 14g), the strip second doped regions (16a, 16b, 16c, 16d, 16e and 16f), the third doped region 18 and the fourth doped region 20 may be doped by any suitable P-type dopant or N-type dopant.

In FIGS. 1 and 2, the width W1 of the strip first doped regions (14a, 14b, 14c, 14d, 14e, 14f and 14g) is the same as the width W2 of the strip second doped regions (16a, 16b, 16c, 16d, 16e and 16f). The depth H1 in the substrate 12 of the strip first doped regions (14a, 14b, 14c, 14d, 14e, 14f and 14g) is the same as the depth H2 in the substrate 12 of the strip second doped regions (16a, 16b, 16c, 16d, 16e and 16f). The depth H3 in the substrate 12 of the third doped region 18 is greater than the depth H1 in the substrate 12 of the strip first doped regions (14a, 14b, 14c, 14d, 14e, 14f and 14g) and the depth H2 in the substrate 12 of the strip second doped regions (16a, 16b, 16c, 16d, 16e and 16f). In some embodiments, The depth H3 in the substrate 12 of the third doped region 18 is the same as the depth H1 in the substrate 12 of the strip first doped regions (14a, 14b, 14c, 14d, 14e, 14f and 14g) and the depth H2 in the substrate 12 of the strip second doped regions (16a, 16b, 16c, 16d, 16e and 16f).

In FIGS. 1 and 2, the doping concentrations of the strip first doped regions (14a, 14b, 14c, 14d, 14e, 14f and 14g), the strip second doped regions (16a, 16b, 16c, 16d, 16e and 16f) and the third doped region 18 are the same. The doping concentration of the fourth doped region 20 is lower than the doping concentrations of the strip first doped regions (14a, 14b, 14c, 14d, 14e, 14f and 14g), the strip second doped regions (16a, 16b, 16c, 16d, 16e and 16f) and the third doped region 18. In some embodiments, the strip first doped regions (14a, 14b, 14c, 14d, 14e, 14f and 14g), the strip second doped regions (16a, 16b, 16c, 16d, 16e and 16f), the third doped region 18 and the fourth doped region 20 may be given an appropriate doping concentration according to product requirements.

In FIGS. 1 and 2, the fourth doped region 20 is a continuous doped region. That is, the fourth doped region 20 located below the strip first doped regions (14a, 14b, 14c, 14d, 14e, 14f and 14g), the strip second doped regions (16a, 16b, 16c, 16d, 16e and 16f) and the third doped region 18 exhibits a continuous doping profile. The strip first doped regions (14a, 14b, 14c, 14d, 14e, 14f and 14g) are high-voltage P-well (HVPW) regions. The strip second doped regions (16a, 16b, 16c, 16d, 16e and 16f) and the third doped region 18 are high-voltage N-well (HVNW) regions. The strip first doped regions (14a, 14b, 14c, 14d, 14e, 14f and 14g), the strip second doped regions (16a, 16b, 16c, 16d, 16e and 16f) and the third doped region 18 constitute a plurality of high-voltage diodes. The fourth doped region 20 serves as an isolation structure between the high-voltage diodes and the substrate 12.

Referring to FIGS. 1 and 2, in accordance with another embodiment of the invention, a semiconductor structure 10 is provided. FIG. 1 is a top view of the semiconductor structure 10. FIG. 2 shows a cross-sectional view of the semiconductor structure 10 shown in FIG. 1 taken along the A-A′ cross-sectional line.

As shown in FIGS. 1 and 2, the semiconductor structure 10 includes a substrate 12, a plurality of strip first doped regions (14a, 14b, 14c, 14d, 14e, 14f and 14g), a plurality of strip second doped regions (16a, 16b, 16c, 16d, 16e and 16f), a third doped region 18 and a fourth doped region 20. The strip first doped regions (14a, 14b, 14c, 14d, 14e, 14f and 14g) are formed in the substrate 12. The strip second doped regions (16a, 16b, 16c, 16d, 16e and 16f) are formed in the substrate 12 and respectively located between the strip first doped regions (14a, 14b, 14c, 14d, 14e, 14f and 14g). For example, the strip first doped regions (14a, 14b, 14c, 14d, 14e, 14f and 14g) and the strip second doped regions (16a, 16b, 16c, 16d, 16e and 16f) are arranged in such a way that they alternate with each other. In FIGS. 1 and 2, the starting point and the ending point of the arrangement of the strip first doped regions (14a, 14b, 14c, 14d, 14e, 14f and 14g) and the strip second doped regions (16a, 16b, 16c, 16d, 16e and 16f) are both the strip first doped regions (for example, 14a and 14g). The third doped region 18 is formed in the substrate 12 and surrounds the strip first doped regions (14a, 14b, 14c, 14d, 14e, 14f and 14g) and the strip second doped regions (16a, 16b, 16c, 16d, 16e and 16f). The third doped region 18 is substantially in contact with the strip first doped regions (14a, 14b, 14c, 14d, 14e, 14f and 14g) and the strip second doped regions (16a, 16b, 16c, 16d, 16e and 16f). The fourth doped region 20 is formed in the substrate 12 and located underneath the strip first doped regions (14a, 14b, 14c, 14d, 14e, 14f and 14g), the strip second doped regions (16a, 16b, 16c, 16d, 16e and 16f) and the third doped region 18. The fourth doped region 20 is substantially in contact with the strip first doped regions (14a, 14b, 14c, 14d, 14e, 14f and 14g), the strip second doped regions (16a, 16b, 16c, 16d, 16e and 16f) and the third doped region 18. In some embodiments, the doping type of the strip first doped regions (14a, 14b, 14c, 14d, 14e, 14f and 14g) is the opposite of that of the strip second doped regions (16a, 16b, 16c, 16d, 16e and 16f). The doping type of the third doped region 18 is the same as that of the strip second doped regions (16a, 16b, 16c, 16d, 16e and 16f). The doping type of the fourth doped region 20 is the same as that of the strip second doped regions (16a, 16b, 16c, 16d, 16e and 16f).

In FIGS. 1 and 2, the doping types of the substrate 12, the strip first doped regions (14a, 14b, 14c, 14d, 14e, 14f and 14g), the strip second doped regions (16a, 16b, 16c, 16d, 16e and 16f), the third doped region 18 and the fourth doped region 20 are as follows. The substrate 12 is an N-type semiconductor substrate. The doping type of the strip first doped regions (14a, 14b, 14c, 14d, 14e, 14f and 14g) is N type. The doping type of the strip second doped regions (16a, 16b, 16c, 16d, 16e and 16f) is P type. The doping type of the third doped region 18 is P type. The doping type of the fourth doped region 20 is P type. In some embodiments, the substrate 12, the strip first doped regions (14a, 14b, 14c, 14d, 14e, 14f and 14g), the strip second doped regions (16a, 16b, 16c, 16d, 16e and 16f), the third doped region 18 and the fourth doped region 20 may be doped by any suitable P-type dopant or N-type dopant.

In FIGS. 1 and 2, the width W1 of the strip first doped regions (14a, 14b, 14c, 14d, 14e, 14f and 14g) is the same as the width W2 of the strip second doped regions (16a, 16b, 16c, 16d, 16e and 16f). The depth H1 in the substrate 12 of the strip first doped regions (14a, 14b, 14c, 14d, 14e, 14f and 14g) is the same as the depth H2 in the substrate 12 of the strip second doped regions (16a, 16b, 16c, 16d, 16e and 16f). The depth H3 in the substrate 12 of the third doped region 18 is greater than the depth H1 in the substrate 12 of the strip first doped regions (14a, 14b, 14c, 14d, 14e, 14f and 14g) and the depth H2 in the substrate 12 of the strip second doped regions (16a, 16b, 16c, 16d, 16e and 16f). In some embodiments, The depth H3 in the substrate 12 of the third doped region 18 is the same as the depth H1 in the substrate 12 of the strip first doped regions (14a, 14b, 14c, 14d, 14e, 14f and 14g) and the depth H2 in the substrate 12 of the strip second doped regions (16a, 16b, 16c, 16d, 16e and 16f).

In FIGS. 1 and 2, the doping concentrations of the strip first doped regions (14a, 14b, 14c, 14d, 14e, 14f and 14g), the strip second doped regions (16a, 16b, 16c, 16d, 16e and 16f) and the third doped region 18 are the same. The doping concentration of the fourth doped region 20 is lower than the doping concentrations of the strip first doped regions (14a, 14b, 14c, 14d, 14e, 14f and 14g), the strip second doped regions (16a, 16b, 16c, 16d, 16e and 16f) and the third doped region 18. In some embodiments, the strip first doped regions (14a, 14b, 14c, 14d, 14e, 14f and 14g), the strip second doped regions (16a, 16b, 16c, 16d, 16e and 16f), the third doped region 18 and the fourth doped region 20 may be given an appropriate doping concentration according to product requirements.

In FIGS. 1 and 2, the fourth doped region 20 is a continuous doped region. That is, the fourth doped region 20 located below the strip first doped regions (14a, 14b, 14c, 14d, 14e, 14f and 14g), the strip second doped regions (16a, 16b, 16c, 16d, 16e and 16f) and the third doped region 18 exhibits a continuous doping profile. The strip first doped regions (14a, 14b, 14c, 14d, 14e, 14f and 14g) are high-voltage N-well (HVNW) regions. The strip second doped regions (16a, 16b, 16c, 16d, 16e and 16f) and the third doped region 18 are high-voltage P-well (HVPW) regions. The strip first doped regions (14a, 14b, 14c, 14d, 14e, 14f and 14g), the strip second doped regions (16a, 16b, 16c, 16d, 16e and 16f) and the third doped region 18 constitute a plurality of high-voltage diodes. The fourth doped region 20 serves as an isolation structure between the high-voltage diodes and the substrate 12.

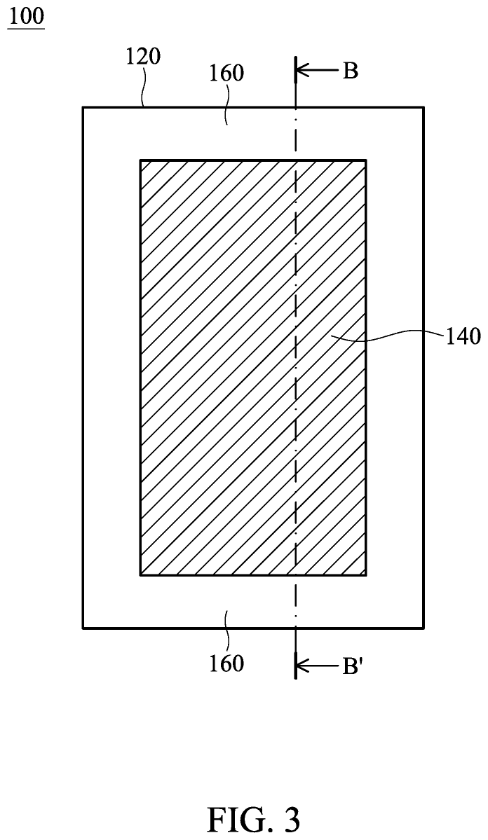

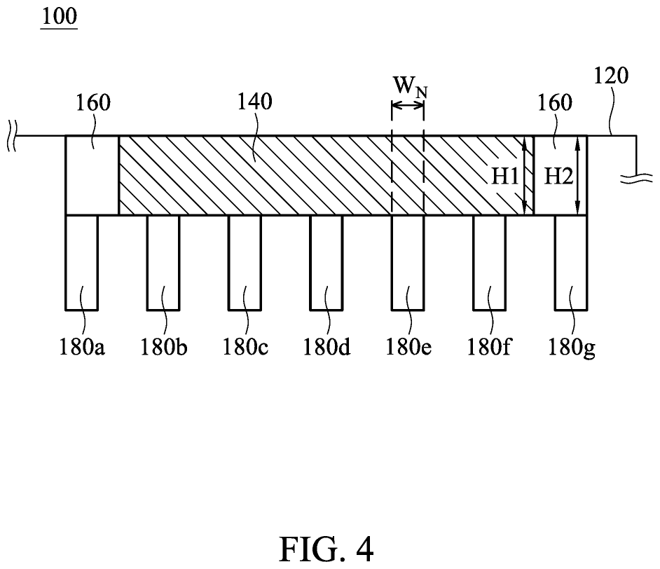

Referring to FIGS. 3 and 4, in accordance with an embodiment of the invention, a semiconductor structure 100 is provided. FIG. 3 is a top view of the semiconductor structure 100. FIG. 4 shows a cross-sectional view of the semiconductor structure 100 shown in FIG. 3 taken along the B-B′ cross-sectional line.

As shown in FIGS. 3 and 4, the semiconductor structure 100 includes a substrate 120, a first doped region 140, a second doped region 160 and a plurality of strip third doped regions (180a, 180b, 180c, 180d, 180e, 180f and 180g). The first doped region 140 is formed in the substrate 120. The second doped region 160 is formed in the substrate 120 and surrounds the first doped region 140. The second doped region 160 is substantially in contact with the first doped region 140. The strip third doped regions (180a, 180b, 180c, 180d, 180e, 180f and 180g) are formed in the substrate 120 and located underneath the first doped region 140 and the second doped region 160. The strip third doped regions (180a, 180b, 180c, 180d, 180e, 180f and 180g) are substantially in contact with the first doped region 140 and the second doped region 160. In some embodiments, the doping type of the first doped region 140 is the opposite of that of the second doped region 160. The doping type of the strip third doped regions (180a, 180b, 180c, 180d, 180e, 180f and 180g) is the same as that of the second doped region 160.

In FIGS. 3 and 4, the doping types of the substrate 120, the first doped region 140, the second doped region 160 and the strip third doped regions (180a, 180b, 180c, 180d, 180e, 180f and 180g) are as follows. The substrate 120 is a P-type semiconductor substrate. The doping type of the first doped region 140 is P type. The doping type of the second doped region 160 is N type. The doping type of the strip third doped regions (180a, 180b, 180c, 180d, 180e, 180f and 180g) is N type. In some embodiments, the substrate 120, the first doped region 140, the second doped region 160 and the strip third doped regions (180a, 180b, 180c, 180d, 180e, 180f and 180g) may be doped by any suitable P-type dopant or N-type dopant.

In FIGS. 3 and 4, the depth H1 in the substrate 120 of the first doped region 140 is the same as the depth H2 in the substrate 120 of the second doped region 160. In some embodiments, the depth H1 in the substrate 120 of the first doped region 140 is different from the depth H2 in the substrate 120 of the second doped region 160. For example, the depth H2 in the substrate 120 of the second doped region 160 is greater than the depth H1 in the substrate 120 of the first doped region 140.

In FIGS. 3 and 4, the doping concentrations of the first doped region 140 and the second doped region 160 are the same. The doping concentration of the strip third doped regions (180a, 180b, 180c, 180d, 180e, 180f and 180g) is lower than the doping concentrations of the first doped region 140 and the second doped region 160. In some embodiments, the first doped region 140, the second doped region 160 and the strip third doped regions (180a, 180b, 180c, 180d, 180e, 180f and 180g) may be given an appropriate doping concentration according to product requirements.

In FIGS. 3 and 4, the strip third doped regions (180a, 180b, 180c, 180d, 180e, 180f and 180g) have the same width W_{N}. The strip third doped regions (180a, 180b, 180c, 180d, 180e, 180f and 180g) are doped regions which are separated from each other. That is, the strip third doped regions (180a, 180b, 180c, 180d, 180e, 180f and 180g) located below the first doped region 140 and the second doped region 160 exhibit a separated doping profile (for example, the strip third doped regions (180a, 180b, 180c, 180d, 180e, 180f and 180g) are separated by the substrate 120). The first doped region 140 is a high-voltage P-well (HVPW) region. The second doped region 160 is a high-voltage N-well (HVNW) region. The first doped region 140 and the second doped region 160 constitute a plurality of high-voltage diodes. In addition, the strip third doped regions (180a, 180b, 180c, 180d, 180e, 180f and 180g) serve as isolation structures between the high-voltage diodes and the substrate 120.

Referring to FIGS. 3 and 4, in accordance with another embodiment of the invention, a semiconductor structure 100 is provided. FIG. 3 is a top view of the semiconductor structure 100. FIG. 4 shows a cross-sectional view of the semiconductor structure 100 shown in FIG. 3 taken along the B-B′ cross-sectional line.

As shown in FIGS. 3 and 4, the semiconductor structure 100 includes a substrate 120, a first doped region 140, a second doped region 160 and a plurality of strip third doped regions (180a, 180b, 180c, 180d, 180e, 180f and 180g). The first doped region 140 is formed in the substrate 120. The second doped region 160 is formed in the substrate 120 and surrounds the first doped region 140. The second doped region 160 is substantially in contact with the first doped region 140. The strip third doped regions (180a, 180b, 180c, 180d, 180e, 180f and 180g) are formed in the substrate 120 and located underneath the first doped region 140 and the second doped region 160. The strip third doped regions (180a, 180b, 180c, 180d, 180e, 180f and 180g) are substantially in contact with the first doped region 140 and the second doped region 160. In some embodiments, the doping type of the first doped region 140 is the opposite of that of the second doped region 160. The doping type of the strip third doped regions (180a, 180b, 180c, 180d, 180e, 180f and 180g) is the same as that of the second doped region 160.

In FIGS. 3 and 4, the doping types of the substrate 120, the first doped region 140, the second doped region 160 and the strip third doped regions (180a, 180b, 180c, 180d, 180e, 180f and 180g) are as follows. The substrate 120 is an N-type semiconductor substrate. The doping type of the first doped region 140 is N type. The doping type of the second doped region 160 is P type. The doping type of the strip third doped regions (180a, 180b, 180c, 180d, 180e, 180f and 180g) is P type. In some embodiments, the substrate 120, the first doped region 140, the second doped region 160 and the strip third doped regions (180a, 180b, 180c, 180d, 180e, 180f and 180g) may be doped by any suitable P-type dopant or N-type dopant.

In FIGS. 3 and 4, the depth H1 in the substrate 120 of the first doped region 140 is the same as the depth H2 in the substrate 120 of the second doped region 160. In some embodiments, the depth H1 in the substrate 120 of the first doped region 140 is different from the depth H2 in the substrate 120 of the second doped region 160. For example, the depth H2 in the substrate 120 of the second doped region 160 is greater than the depth H1 in the substrate 120 of the first doped region 140.

In FIGS. 3 and 4, the doping concentrations of the first doped region 140 and the second doped region 160 are the same. The doping concentration of the strip third doped regions (180a, 180b, 180c, 180d, 180e, 180f and 180g) is lower than the doping concentrations of the first doped region 140 and the second doped region 160. In some embodiments, the first doped region 140, the second doped region 160 and the strip third doped regions (180a, 180b, 180c, 180d, 180e, 180f and 180g) may be given an appropriate doping concentration according to product requirements.

In FIGS. 3 and 4, the strip third doped regions (180a, 180b, 180c, 180d, 180e, 180f and 180g) have the same width W_{N}. The strip third doped regions (180a, 180b, 180c, 180d, 180e, 180f and 180g) are doped regions separated from each other. That is, the strip third doped regions (180a, 180b, 180c, 180d, 180e, 180f and 180g) located below the first doped region 140 and the second doped region 160 exhibits a separated doping profile (for example, the strip third doped regions (180a, 180b, 180c, 180d, 180e, 180f and 180g) are separated by the substrate 120). The first doped region 140 is a high-voltage N-well (HVNW) region. The second doped region 160 is a high-voltage P-well (HVPW) region. The first doped region 140 and the second doped region 160 constitute a plurality of high-voltage diodes. In addition, the strip third doped regions (180a, 180b, 180c, 180d, 180e, 180f and 180g) serve as isolation structures between the high-voltage diodes and the substrate 120.

### Example 1

Tests of Breakdown Voltage (BV) of High-Voltage Diodes

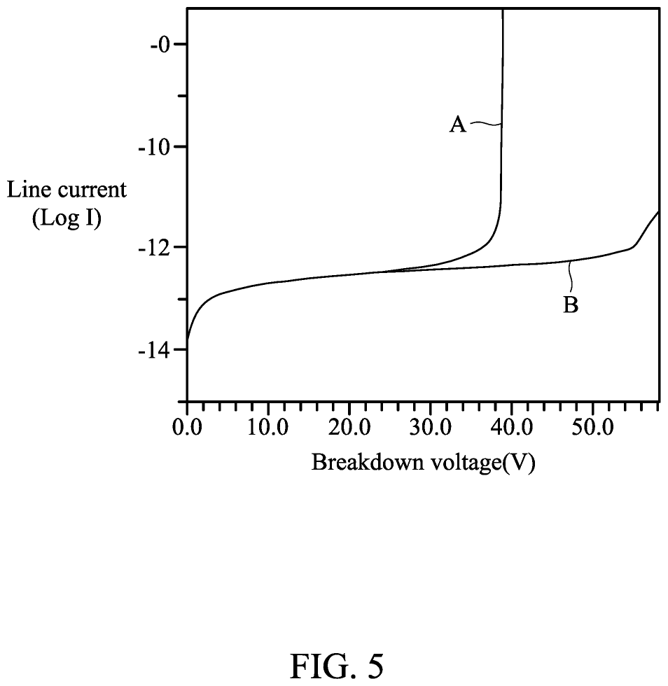

Referring to FIG. 5, in this embodiment, the tests of the breakdown voltage (BV) of a conventional high-voltage diode and the present high-voltage diode are performed. Here, the structure of the conventional high-voltage diode includes a high-voltage P-well (HVPW) region, a high-voltage N-well (HVNW) region and a deep N-well (DNW) region. The high-voltage P-well (HVPW) region is a continuous doped region extending over the entire substrate surface. The high-voltage N-well (HVNW) region surrounds the high-voltage P-well (HVPW) region. The deep N-well (DNW) region is located underneath the high-voltage P-well (HVPW) region and the high-voltage N-well (HVNW) region. The structure of the present high-voltage diode includes a plurality of strip high-voltage P-well (HVPW) regions, a plurality of strip high-voltage N-well (HVNW) regions, a high-voltage N-well (HVNW) region and a deep N-well (DNW) region. The strip high-voltage P-well (HVPW) regions and the strip high-voltage N-well (HVNW) regions are arranged in such a way that they alternate with each other. The high-voltage N-well (HVNW) region surrounds the strip high-voltage P-well (HVPW) regions and the strip high-voltage N-well (HVNW) regions. The deep N-well (DNW) region is located underneath the strip high-voltage P-well (HVPW) regions, the strip high-voltage N-well (HVNW) regions and the high-voltage N-well (HVNW) region, as shown in FIGS. 1 and 2. After the tests are performed, the variations of the breakdown voltage (BV) measured from the above components are shown as curve A (the conventional high-voltage diode) and curve B (the present high-voltage diode) in FIG. 5.

It can be seen from FIG. 5 that the breakdown voltage (BV) of the conventional high-voltage diode (curve A) fails to reach 40 volts, which is far from the value of the breakdown voltage (BV) required for ordinary high-voltage components during operation. However, in the high-voltage diode of the present invention, the high-voltage P-well (HVPW) regions and the high-voltage N-well (HVNW) regions are respectively designed as a plurality of doped regions in the form of strips, which are arranged in such a way that they alternate with each other, thereby greatly increasing the junction area of the P-N. The high-voltage diode can thus effectively disperse the generated electric field during operation, thereby increasing its breakdown voltage (BV) to more than 60 volts (curve B). The high-voltage diode with such a sufficiently large breakdown voltage (BV) of the present invention can be widely used in a circuit system including various high-voltage components.

By adjusting the doping profile, the present invention replaces the conventional high-voltage P-well (HVPW) region extending over the entire substrate surface to form a plurality of doped regions in the form of strips. The strip high-voltage P-well (HVPW) regions are combined with a plurality of high-voltage N-well (HVNW) regions and arranged in such a way that they alternate with each other to form the specific high-voltage diode structure. Due to the arrangement of the plurality of strip doped regions of the present invention, the junction area of the P-N is greatly increased, so that the high-voltage diode can effectively disperse the generated electric field during operation, even in the presence of the deep N-well (DNW) region, the breakdown voltage (BV) of the high-voltage diode can still greatly increased by more than 80%. In addition, the present invention can directly introduce the above-mentioned high-voltage diode structure without changing the MOS processes, the implanting conditions, and the photomask combination. The present invention does not affect the breakdown voltage (BV) of other high-voltage components provided in the same circuit system as the above-mentioned high-voltage diode structure, ensuring the electrical stability of such high-voltage components, thereby maintaining the stability and performance of the overall circuit.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor structure, comprising:
a substrate;
a plurality of strip first doped regions formed in the substrate;
a plurality of strip second doped regions formed in the substrate and respectively located between the strip first doped regions, wherein the strip first doped region has a doping type which is opposite that of the strip second doped region;
a third doped region formed in the substrate and surrounding the strip first doped regions and the strip second doped regions, wherein the third doped region has a doping type which is the same as that of the strip second doped region; and
a fourth doped region formed in the substrate and located underneath the strip first doped regions, the strip second doped regions and the third doped region, wherein the fourth doped region has a doping type which is the same as that of the strip second doped region.

2. The semiconductor structure as claimed in claim 1, wherein the substrate is a P-type substrate or an N-type substrate.

3. The semiconductor structure as claimed in claim 2, wherein when the substrate is a P-type substrate, the doping type of the strip first doped region is P type, the doping type of the strip second doped region is N type, the doping type of the third doped region is N type, and the doping type of the fourth doped region is N type.

4. The semiconductor structure as claimed in claim 2, wherein when the substrate is an N-type substrate, the doping type of the strip first doped region is N type, the doping type of the strip second doped region is P type, the doping type of the third doped region is P type, and the doping type of the fourth doped region is P type.

5. The semiconductor structure as claimed in claim 1, wherein the strip first doped region has a width which is the same as that of the strip second doped region.

6. The semiconductor structure as claimed in claim 1, wherein the strip first doped region has a depth in the substrate which is the same as that of the strip second doped region.

7. The semiconductor structure as claimed in claim 6, wherein the third doped region has a depth in the substrate which is greater than that of the strip first doped region and the strip second doped region.

8. The semiconductor structure as claimed in claim 1, wherein the strip first doped region, the strip second doped region and the third doped region have the same doping concentration.

9. The semiconductor structure as claimed in claim 8, wherein the fourth doped region has a doping concentration which is lower than that of the strip first doped region, the strip second doped region and the third doped region.

10. The semiconductor structure as claimed in claim 1, wherein the fourth doped region is a continuous doped region.

11. The semiconductor structure as claimed in claim 3, wherein the strip first doped region is a high-voltage P-well region, and the strip second doped region and the third doped region are high-voltage N-well regions.

12. The semiconductor structure as claimed in claim 11, wherein the strip first doped regions, the strip second doped regions and the third doped region constitute a plurality of high-voltage diodes.

13. A semiconductor structure, comprising:
a substrate;
a first doped region formed in the substrate;
a second doped region formed in the substrate and surrounding the first doped region, wherein the first doped region has a doping type which is opposite that of the second doped region; and
a plurality of strip third doped regions formed in the substrate and located underneath the first doped region and the second doped region,
wherein the strip third doped region has a doping type which is the same as that of the second doped region.

14. The semiconductor structure as claimed in claim 13, wherein the substrate is a P-type substrate or an N-type substrate.

15. The semiconductor structure as claimed in claim 14, wherein when the substrate is a P-type substrate, the doping type of the first doped region is P type, the doping type of the second doped region is N type, and the doping type of the strip third doped region is N type.

16. The semiconductor structure as claimed in claim 14, wherein when the substrate is an N-type substrate, the doping type of the first doped region is N type, the doping type of the second doped region is P type, and the doping type of the strip third doped region is P type.

17. The semiconductor structure as claimed in claim 13, wherein the first doped region has a depth in the substrate which is the same as that of the second doped region.

18. The semiconductor structure as claimed in claim 13, wherein the first doped region has a doping concentration which is the same as that of the second doped region.

19. The semiconductor structure as claimed in claim 18, wherein the strip third doped region has a doping concentration which is lower than that of the first doped region and the second doped region.

20. The semiconductor structure as claimed in claim 13, wherein the strip third doped regions have the same width.

21. The semiconductor structure as claimed in claim 13, wherein the strip third doped regions are separated from each other.

22. The semiconductor structure as claimed in claim 15, wherein the first doped region is a high-voltage P-well region, and the second doped region is a high-voltage N-well region.

23. The semiconductor structure as claimed in claim 22, wherein the first doped region and the second doped region constitute a plurality of high-voltage diodes.
